(19) United States
(12) Patent Application Publication
(10) Pub. No.: US 2013/0156054 A1
(43) Pub. Date: Jun. 20, 2013

(54) MONOLITHIC, FIBER-TO-FIBER COUPLED NONLINEAR RESONATOR FOR BREWSTER CUT PERIODICALLY POLED CRYSTALS

(71) Applicant: University of North Texas System, Denton, TX (US)

(72) Inventors: Koustubh Danekar, Florence, NJ (US); David Shiner, Farmers Branch, TX (US); Ali Khademian, Denton, TX (US)

(73) Assignee: University of North Texas System, Denton, TX (US)

(21) Appl. No.: 13/814,680

(22) PCT Filed: Aug. 5, 2011
(86) PCT No.: PCT/US11/46803

§ 371 Date: Mar. 1, 2013

Related U.S. Application Data
(60) Provisional application No. 61/371,551, filed on Aug. 6, 2010.

(51) Int. Cl. H01S 5/06

(52) U.S. Cl. CPC H01S 5/0604
USPC 372/21

(57) ABSTRACT

An apparatus and method for nonlinear conversion of laser light is described herein. The apparatus of the instant invention comprises a fiber coupled light source, a cavity in optical alignment with the first light beam from the light source, wherein the cavity comprises: two concave mirrors, one or more Brewster-cut periodically poled crystals, and a cavity servo to lock the length of cavity to laser frequency. In one aspect of the present invention the feedback to the lock is S-polarized component of first laser light reflected off the Brewster surface of nonlinear crystal.

### TECHNICAL FIELD OF THE INVENTION

The present invention relates in general to the field of nonlinear resonators, and more particularly, to a monolithic, fiber-to-fiber coupled, low cost, high efficiency, nonlinear resonator for Brewster cut periodically poled crystals.

### BACKGROUND ART

Without limiting the scope of the invention, its background is described in connection with laser performance.

Blue diode lasers are commercially available, but they do not yet match the performance of the well-developed IR semiconductor lasers. Nonlinear doubling these IR lasers offer an alternative blue laser source of high power.

An optical resonant frequency converter comprising two mirrors and a non-linear crystal in a ring resonator arrangement for converting laser radiation into frequency-doubled radiation is described in U.S. Pat. No. 7,027,209 issued to Zanger and Salzman (2006) In the '209 invention because of the refractive effect of the prism-shaped, non-linear crystal two mirrors are sufficient to form a ring resonator with a total of three optical elements. A suitable choice of the orientation of the crystal axes in relation to the laser beam direction reduces scatter in the crystal. In one embodiment of the Zanger invention the entry surface of the crystal is at the Brewster angle while the exit surface is perpendicular to the beam and has an antireflection coating. In another embodiment the converted beam is coupled out through a polarisation beam splitter layer on one of the crystal surfaces. In a further embodiment the crystal surfaces are cylindrically curved. That produces an elliptical beam profile in the crystal, which reduces the walk-off effect.

U.S. Pat. No. 5,027,361 issued to Kozlovsky et al. (1991) discloses a laser harmonic generator for converting laser energy of an input beam from a fundamental wavelength of said beam to a harmonic of that wavelength. The Kozlovsky invention comprises an optical resonator configured to resonate said fundamental wavelength and having an input coupler for introducing said input beam into the same and a non-linear material within said resonator for generating said harmonic by conversion of said fundamental wavelength, said input coupler being impedance matched to said resonator taking into account the conversion loss to said harmonic. The inventors applied an electric field to the crystal which can be source of significant optical loss and degradation of conversion efficiency due to resulting localized charge distribution.

U.S. Pat. No. 7,460,570 (Katsuyuki et al. 2008) teaches a small-scale device, that is a second harmonic generating device of a laser beam with which high-quality and large output light is obtained efficiently and stably by the use of a standing wave linear cavity as opposed to ring type cavity structure.

U.S. Pat. No. 5,206,868 (Deacon, 1993) describes a resonant nonlinear laser beam converter. The '868 patent uses a ring cavity structure with one nonlinear crystal for harmonic generation.

### DISCLOSURE OF THE INVENTION

The present invention includes an apparatus and method for nonlinear conversion of laser light comprising a fiber coupled light source; a cavity in optical alignment with the first light beam from the light source, wherein the cavity comprises: two concave mirrors; and one or more Brewster-cut periodically poled crystals; and a cavity servo to lock the length of cavity to laser frequency wherein the feedback to the lock is S-polarized component of first laser light reflected off the Brewster surface of nonlinear crystal.

A nonlinear resonator apparatus is described in one embodiment of the instant invention. The apparatus comprises, a fiber coupled to a light source that generates a first light beam and a ring cavity in optical alignment with the first light beam from the light source, wherein the cavity comprises: (i) two concave mirrors and (ii) one or more Brewster-cut periodically poled crystals with a S-polarized component of the first light beam reflected off of a Brewster surface serving as a feedback signal for a servo locking of a cavity length to a first light frequency, wherein the servo locking is done at a high frequency. In one aspect the crystal comprises a periodically poled LiNbO₃ (PPLN), a LiTaO₃ (PPLT), a KTiOPO₄ (PPKTP) or any suitable periodically poled crystals. In another aspect the apparatus does not include a dichroic mirror in the cavity. In another aspect there is very low intrinsic loss within the cavity due to a clean separation of the first light beam and a second light beam or a second harmonic without the use of a dichroic mirror. In yet another aspect the apparatus comprises a coupling aspheric lens that is positioned along an optical axis of a second separated light beam that exits the cavity, wherein the second beam exits the cavity at near Brewster angle at which the first light beam exits. In another aspect the comprising an input PM fiber in optical alignment with the coupling aspheric lens.

The apparatus described hereinabove polarizes a circulating power of the first and the second light beams in a direction parallel to an orientation of periodic poling direction within the crystal. In specific aspects the first light source is a laser or an infrared laser. In one aspect the first, second or both light beams traverse an optical fiber. In another aspect the apparatus comprises a customized output mirror on a customized flexure mount, wherein the mount is translated in a plane perpendicular to the incoming second light beam. In yet another aspect the entire apparatus is made monolithic and fiber to fiber coupled by a coupling of the second light beam into a fiber by a beam shaping optics arrangement.

In another embodiment the present invention provides a method of separating light wavelengths comprising the steps of: generating a first light beam directed at a cavity in optical alignment with an laser beam from the laser source, wherein the cavity comprises: two concave mirrors and one or more Brewster-cut periodically poled crystals with a S-polarized component of the first light beam reflected off of a Brewster surface serving as a feedback signal for a servo locking of a cavity length to a first light frequency, wherein the servo locking is done at a high frequency.

In one aspect the crystal comprises a periodically poled LiNbO₃ (PPLN), LiTaO₃ (PPLT), KTiOPO₄ (PPKTP) or any suitable periodically poled crystals. In another aspect the apparatus does not include a dichroic mirror in the cavity. In yet another aspect a coupling aspheric lens that is positioned along an optical axis of a second separated light beam that exits the cavity, wherein the second beam exits the cavity at near Brewster angle at which the first light beam exits. In another aspect an input PM fiber in optical alignment with the coupling aspheric lens. In related aspects the first light source is a laser or an infrared laser and the first, second or both light beams traverse an optical fiber.

Yet another embodiment of the instant invention discloses a monolithic, nonlinear resonator comprising laser source: (i) an infrared laser source that generates a first light beam and (ii) a cavity in optical alignment with the first light beam from the light source, wherein the cavity comprises: (a) two concave mirrors and (b) one or more Brewster-cut periodically poled crystals with a S-polarized component of the first light beam reflected off of a Brewster surface serving as a feedback signal for a servo locking of a cavity length to a first light frequency, wherein the servo locking is done at a high frequency. In one aspect the crystal comprises a periodically poled LiNbO₃ (PPLN), LiTaO₃ (PPLT), KTiOPO₄ (PPKTP) or any suitable periodically poled crystals. In another aspect the apparatus does not include a dichroic mirror in the cavity. In another aspect the apparatus performs a non dichroic mirror based separation of the first light beam and a second light beam or a second harmonic. In yet another aspect the apparatus further comprises a coupling aspheric lens that is positioned along an optical axis of a second separated light beam that exits the cavity, wherein the second beam exits the cavity at near Brewster angle at which the first light beam exits.

In one aspect the apparatus further comprises an input PM fiber in optical alignment with the coupling aspheric lens. In another aspect the apparatus polarizes a circulating power of the first and the second light beams in a direction parallel to an orientation of periodic poling direction within the crystal. In another aspect the first light source is a laser. In another aspect the first light source is an infrared laser. In yet another aspect the first, second or both light beams traverse an optical fiber. Further, the apparatus comprises a customized output mirror on a customized flexure mount, wherein the mount is translated in a plane perpendicular to the incoming second light beam. Finally, the entire apparatus is made monolithic and fiber to fiber coupled by a coupling of the second light beam into a fiber by a beam shaping optics arrangement.

The apparatus of the present invention embodies multiple novel features and provides significant advantages over other resonator apparatus devices. The apparatus of the present invention has a very low intrinsic loss within cavity due to polarization of circulating power of first harmonic power and the second harmonic generated power parallel to the orientation of periodic poling direction within crystal and a very low intrinsic loss due to clean separation of fundamental and second harmonic without use of dichroic mirror

The method of clean separation in the apparatus described hereinabove is assisted by use of Brewster polished crystal wherein the second light or second harmonic generated beam also exits the crystal at near Brewster angle at which first light exits. The clean separation is also assisted by loading the customized output mirror on a customized flexure mount which can be translated in a plane perpendicular to the incoming second harmonic beam. Due to small size of custom cut high reflector, the present inventors were able to use high frequency for servo locking the length of cavity to the laser. The apparatus has a low cost of production of cavity due to monolithic feature of each flexure mount and by the non-use of bulky knobs. By coupling the second harmonic generated beam into fiber via a beam shaping optics all placed on the same plate, makes the entire apparatus monolithic, fiber to fiber coupled. Thus, the significant features of cavity and the apparatus of the present invention are compactness, higher efficiency and low production cost.

### DESCRIPTION OF THE DRAWINGS

For a more complete understanding of the features and advantages of the present invention, reference is now made to the detailed description of the invention along with the accompanying figures and in which:

FIG. 1 is a schematic diagram shows detailed cavity structure for harmonic generation with a FBG stabilized semiconductor module pigtailed with PM fiber output. The crystal is periodically poled with servo locking to the beam reflected at Brewster angle. It also shows beam fundamental and harmonic beams entering and exiting the cavity;

FIG. 2A is a top view of cavity assembly of present invention, with PM fibers at the input and exit ends;

FIG. 2B is an exploded view of cavity assembly of present invention;

FIG. 2C is bottom view of cavity plate of present invention;

FIG. 3A is an isometric view input flexure mount assembly with PM fiber at entrance;

FIG. 3B is the side view of input flexure mount assembly with PM fiber at entrance;

FIG. 3C is the exploded view of input flexure mount assembly with PM fiber at entrance;

FIG. 3D is the side view of fundamental coupling lens assembly;

FIG. 4A is the isometric view of input flexure mount with turning mirror for fundamental beam;

FIG. 4B is the top view of input flexure mount with turning mirror;

FIG. 5A is the isometric view of input flexure mount with partial reflector;

FIG. 5B is the exploded view of input flexure mount with partial reflector;

FIG. 5C is the rear view of input flexure mount with partial reflector;

FIG. 6A is the exploded isometric view of crystal mount with Brewster cut crystal;

FIG. 6B is the bottom view of crystal mount assembly with Brewster cut crystal;

FIG. 7A is the isometric view of flexure mount with fundamental beam, high reflector mirror of cavity glued on piezo;

FIG. 7B shows location of piezo and mirror with respect to z-axis of rotation;

FIG. 7C shows alternate arrangement for clamping output cavity mount to the base plate;

FIG. 8 is the isometric view of output flexure mount with turning mirror for harmonic generated beam;

FIG. 9 is the exploded side view of output flexure mount assembly with PM fiber at exit;

FIG. 10 shows the back view of base plate placed on top of thermoelectric coolers;

FIG. 11 is a graph that shows Blue vs IR power; and

FIG. 12 is a graph that shows Blue conversion vs IR power.

### DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

The term “optical fiber” as used herein generally refers to conventional glass or plastic filaments made for the transmission of light. Such fibers are typically between 5 and 100 microns in diameter and are typically clad with a layer of another transparent material having a lower index of refraction.

The term “lens” as used herein in various embodiments refers to an optical device with perfect or approximate axial symmetry which transmits and refracts light, converging or diverging the beam. In systems of lens elements, the term “optical axis” usually refers to the symmetry axis of the lens system. As used herein, the term “aspheric lens” refers to a lens in which at least one surface of the lens is shaped to a non-spherical surface of revolution about an axis of revolution.

A “concave mirror”, or a “converging mirror”, as used in the present invention refers to a reflecting surface that bulges inward (away from the incident light). “Concave mirrors” reflect light inward to one focal point and are used to focus light.

The terms “Brewster's angle” or Brewster angle” is used to refer to the angle of incidence, i.e., the angle between a radiation beam and a dielectric surface normal that corresponds to the minimum or near-minimum reflectivity of the P-polarized component of the beam.

As used herein in the present application and the claims the term “dichroic mirror” implies a mirror which allows selective transmission or reflection of beams whose wavelengths are within a predetermined range.

The term “second harmonic” as used herein includes the so-called two photon absorption effect. The instantaneous appearance of two photons cannot be distinguished from the second harmonic. A discussion of second harmonic generation and two photon absorption may be found in an article entitled “Non Linear Optics” by R. W. Minck, R. W. Terhune and C. C. Wang in APPLIED OPTICS, October, 1966, pages 1595-1612, relevant portions of which are incorporated herein by reference.

The term “laser” as used herein is an acronym for Light Amplification by Stimulated Emission of Radiation. Although the term “laser” is specific to electromagnetic radiation in the light frequency spectrum, apparatus are known for amplifying many frequencies of electromagnetic radiation by the stimulated emission of radiation. The term “infrared laser” is used herein to denote a laser having a wavelength of 2 μm or less.

The term “light frequency ” or “light wave frequency” is used herein to refer to frequencies including the visible light range as well as frequency in the near and far infrared range and in the ultraviolet range.

The term “wavelength” as used in the specification and the claims refers to the actual physical length comprising one full period of electromagnetic oscillation of a light ray or light beam.

The present invention is nonlinear frequency conversion, red, blue or green light and can be generated by using any periodically poled crystals in the same cavity design. The lasers of the present invention find applications in various fields, for instance, in medicine; lasers operating around 488±50 nm are used for flow cytometry and DNA sequencing. This is based on fluorescence excitation of dye labels attached on the sample under study; a technique also used in confocal laser scanning microscopy to generate 3D image of specimens. On similar lines, excitation of photo sensitizers in photodynamic therapy requires a high-powered laser (630-660 nm), for penetration greater than an inch in the tissue. Other uses for the present invention include scientific, commercial and industrial applications like laser cooling, atomic and molecular spectroscopy, Raman spectroscopy, LIDAR, laser light displays, optical tweezers, lithography, etc.

The present invention allows for an unprecedented compactness also allows the apparatus to be used to retrofit any applications like spectroscopy without taking apart/or ridding entire apparatus. Furthermore, the present invention can also be adapted to permit Spontaneous parametric down conversion (SPDC) to generate entangled photons. For instance, the high-powered blue light source of the present invention can be used to generate twin photons by SPDC. Current processes are intrinsically inefficient, the present invention can be used with similar cavity technique to increase efficiency. For example, the present invention can be used to enable long distance quantum teleportation by coupling entangled photons through lossy standard telecom fibers.

The present invention provides various unique features and significant advantages and advancements over the existing prior art. Using Brewster angle for low transmission loss of P-polarization of fundamental beam has been shown (U.S. Pat. No. 7,027,209 as previously described) and demonstrated by Lunderman, et al., but the unique design feature of the instant invention is the use of S-polarization reflected off the Brewster surface for servo locking of cavity length to laser frequency. This has allowed our cavity design to be compact. Further on the same lines of compactness, due to monolithic design of the cavity there is excellent beam stability at the high power buildup of fundamental beam with temperature of crystal tuned to be off resonant i.e., no blue creation. Also, in addition to the long term mechanical stability the cavity is seen to retain alignment for a long time.

The present invention embodies novel concepts and unique features that are absent in related devices in the prior art. In comparison to the monolithic nonlinear converter by Kozlovsky et al. (U.S. Pat. No. 5,027,361) the present invention does not apply an electric field directly to the crystal but uses a piezo on which mirror is loaded to change the length of cavity. This has shown stable results even up to 600 mw of blue generation at 486 nm. In U.S. Pat. No. 7,460,570 (Katsuyuki et al.) uses a standing wave linear cavity as opposed to ring type cavity structure of the present invention, for nonlinear conversion. Katsuyuki also use a bulk crystal against the PP structure herein and hence have lower single pass conversion efficiency and relative much higher losses due to walk-off U.S. Pat. No. 5,206,868 issued to Deacon uses a ring cavity st45rgb structure with one nonlinear crystal for harmonic generation, but they use a dichroic mirror and a bulk crystal both of which contribute more losses to the cavity.

In addition to the advantages over the prior art, the apparatus of the present invention has a very low intrinsic loss within cavity due to polarization of circulating power of first harmonic power and the second harmonic generated power parallel to the orientation of periodic poling direction within crystal and a very low intrinsic loss due to clean separation of fundamental and second harmonic without use of dichotic mirror

The method of clean separation in the apparatus described hereinabove is assisted by use of Brewster polished crystal wherein the second light or second harmonic generated beam also exits the crystal at near Brewster angle at which first light exits. The clean separation is also assisted by loading the customized output mirror on a customized flexure mount which can be translated in a plane perpendicular to the incoming second harmonic beam, as described below.

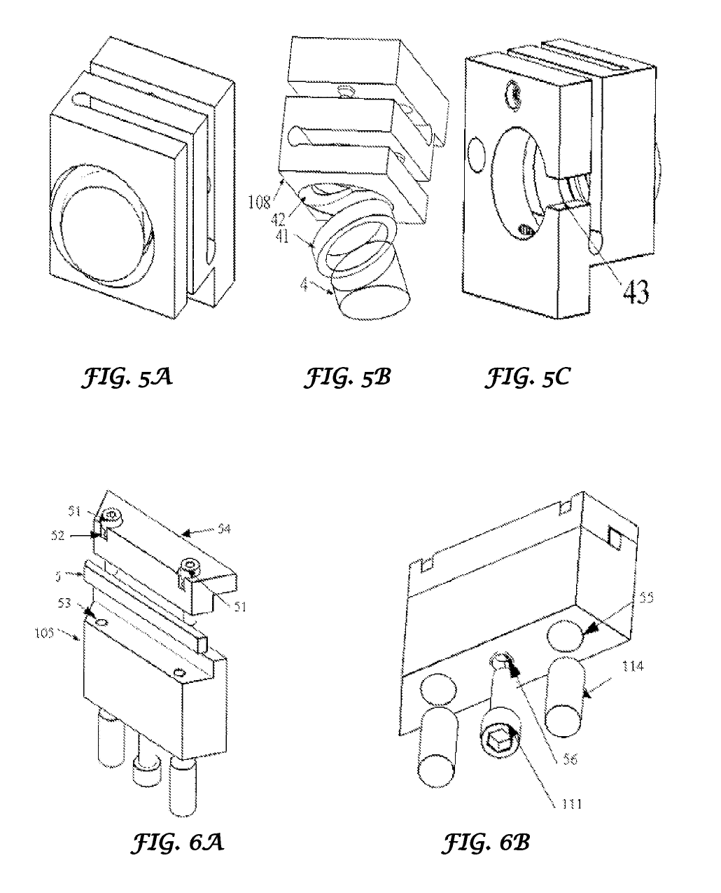

The first light is reflected cleanly by use of mechanism described in FIGS. 5A-5C. The significance lies in the location of loading output mirror which makes alignment of cavity more convenient. Both mirror and piezo have been placed at the pivotal edge of flexure mount which defines the axis of rotation for horizontal tilt. Hence translation of mirror along the arc with its center at the flexure pivot, due to horizontal tilt of mount is minimized since mirror is sitting close to center of axis about which its being tilted which leaves the beam separation unaffected

Due to small size of custom cut high reflector, the present inventors were able to use high frequency for servo locking the length of cavity to the laser. The apparatus has a low cost of production of cavity due to monolithic feature of each flexure mount and by the non-use of bulky knobs. By coupling the second harmonic generated beam into fiber via a beam shaping optics all placed on the same plate, makes the entire apparatus monolithic, fiber to fiber coupled. Thus, the significant features of cavity and the apparatus of the present invention are compactness, higher efficiency and low production cost.

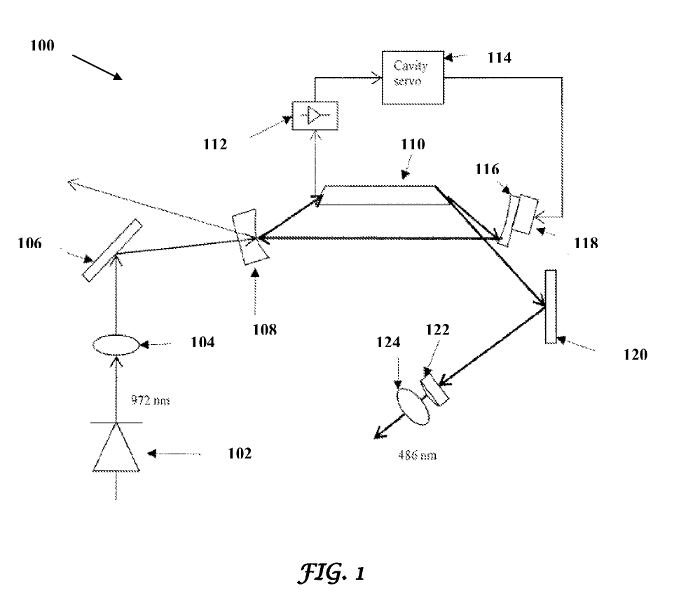

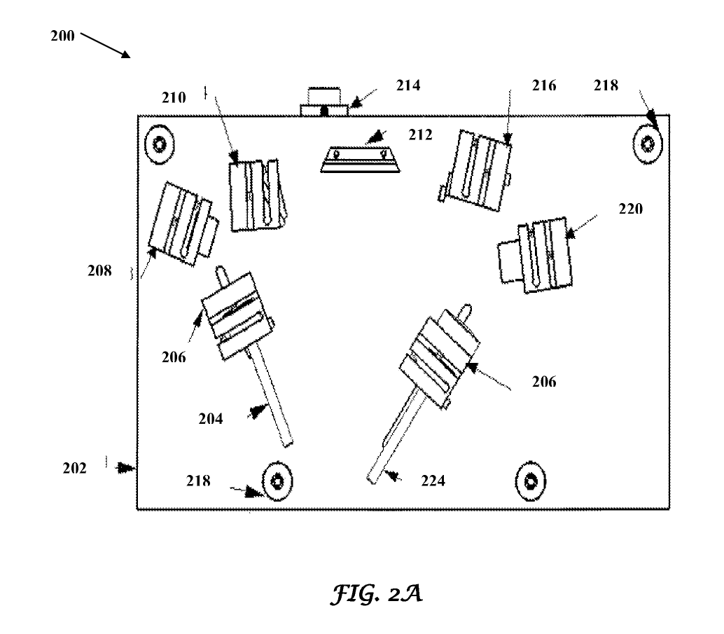

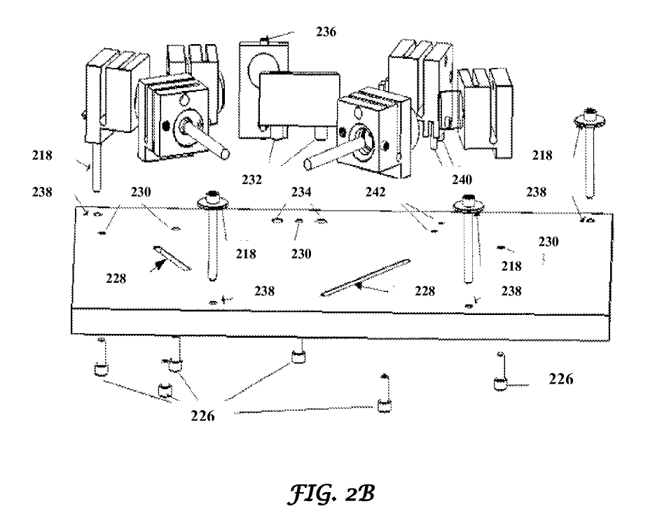

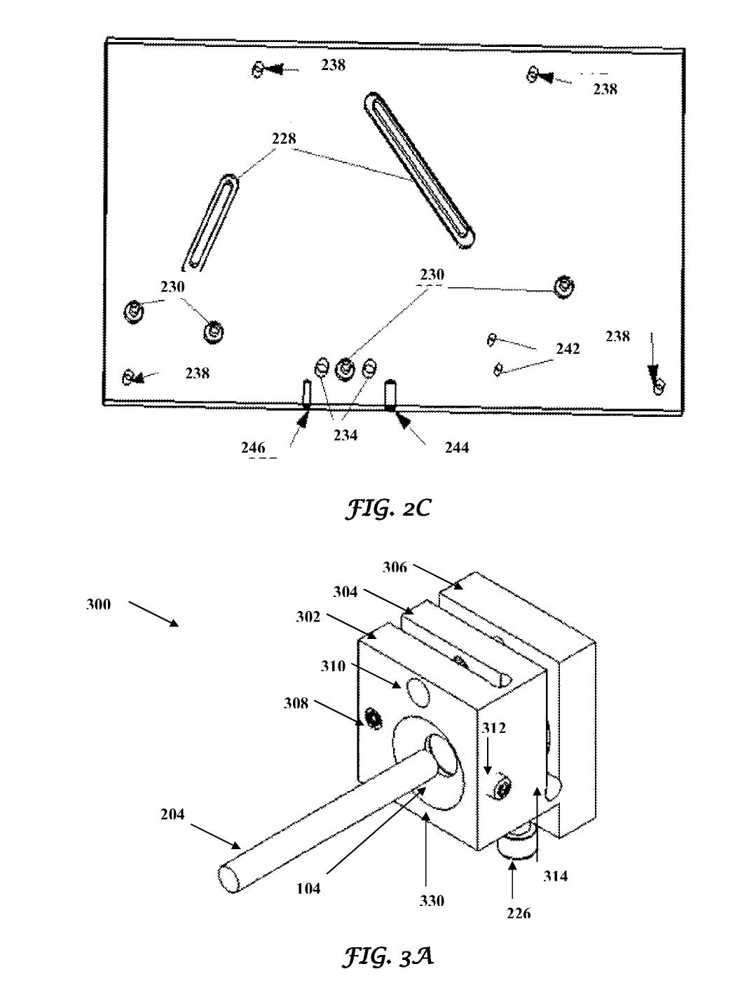

In addition to the advantages mentioned above, the instant invention provides a clean separation of fundamental and second harmonic beam, after emerging at the exit end of crystal, by employing a special design of output cavity flexure mount (216 shown in FIG. 2A), and careful customized size of output high reflector 116 shown in FIG. 1. This has allowed reducing the cost of production by avoiding the need for more expensive dichroic mirror like in case of Lunderman, et al., and low intrinsic loss of fundamental as well as harmonic beam generated. Also, the complicated optics involved in beam shaping has been circumvented by special arrangement of input PM fiber connector with respect to optic axis of coupling aspheric lens. The has allowed the present inventors to achieve up to 96% mode matching in the cavity, one of highest reported value.

Another feature of the instant invention is a stable power (fluctuation within 2% of maximum) of harmonic generation when servo locked. This is attributed to intrinsic uniform thermal distribution within the cavity due to monolithic design. Another interesting feature is larger angle of acceptance. But this is intrinsic to periodically poled crystals and not novel to the design of the instant invention.

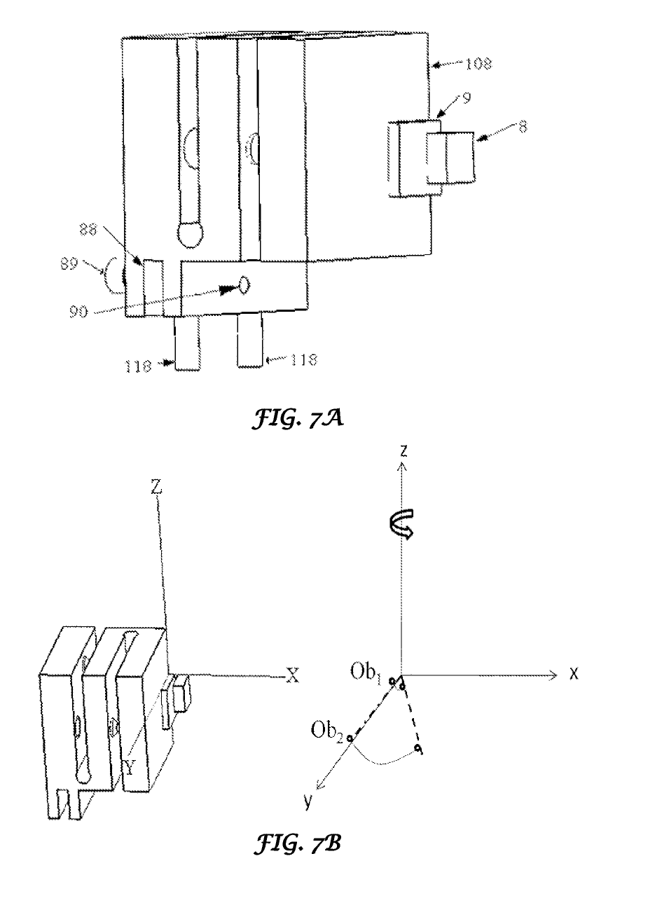

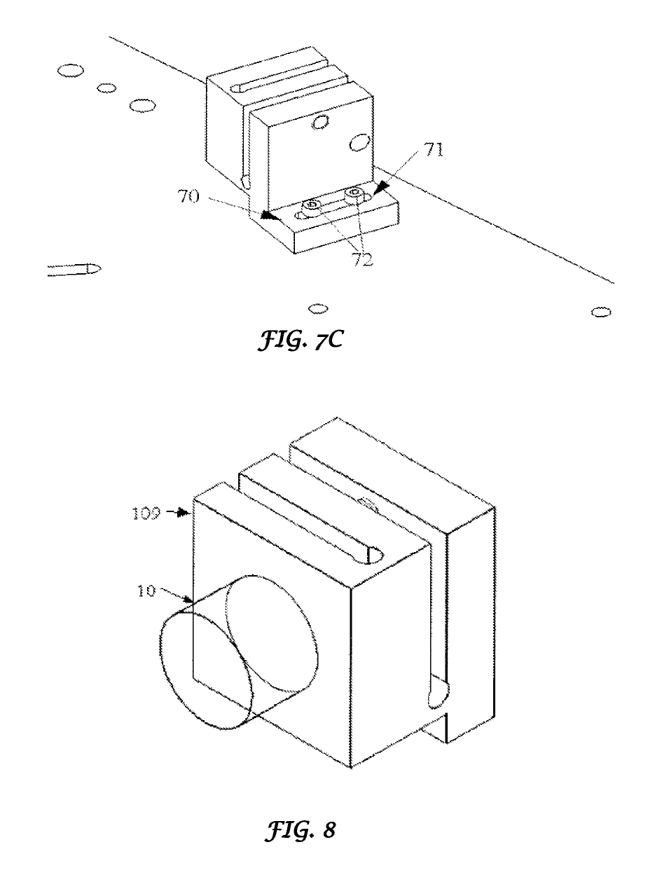

Also in the present invention small size of custom cut high reflector 116 and piezo 118, shown in FIG. 7A, allow for high modulation frequency (˜40 kHz) to be used in locking, reducing sensitivity to flicker (1/f) noise on top of DC high voltage. The salient features of the cavity of the present invention can be summarized herein below: (i) compactness and convenience, (ii) low intrinsic loss due to Brewster cut edges, (iii) low cost of production due to use of standard high reflectors, simple Brewster cut crystal geometry avoiding need for anti-reflection coating and state of art minor cutting technology allowing more pieces to be cut from one commercial standard piece and the elimination of the need to use of expensive dichroic minor for high reflector, (iv) clean separation of SHG and Fundamental beams due to customized high reflector cut from standard commercial high reflector. This feature was enabled due to translation ability of the output cavity mount 216 in FIG. 2A, (v) Long term thermal and mechanical stability due to monolithic feature of cavity, (vi) Temperature range for stable output of high power second harmonic output in our cavity is 0.5° C. This is again enabled by use of monolithic design for cavity, (vii) Again monolithic design also allows for convenient use of thermoelectric cooler instead of introducing any external oven for the crystal. This feature leads to compactness and low cost of production as well, (viii) By avoiding use of bulky knobs for adjustment of tilt and small size of each of flexure mounts, plurality of these mounts can be arranged in a compact and efficient way, without introducing any optical distortion, (ix) The cost of production is also lowered since each flexure mount is a monolithic unit and doesn't involve the welding process to join separate parts and strings for flexing motion, and (x) Due to presence of input turning mirror 3, the incident angle of fundamental beam with respect to normal to the crystal face can be changed without necessarily spatially shifting the point of incidence of the beam on the crystal and vice versa.

FIG. 1 shows elements of optical resonator 100 with fundamental input from FBG stabilized semiconductor laser 102 pigtailed with PM fiber output. The beam then passes through coupling lens 104, which focuses the fundamental beam at the center of the crystals in the cavity, with diameter corresponding to cavity parameters. Before entering cavity, the beam is reflected off from turning mirror 106, which allows for horizontal and vertical tuning of beam location on the entrance and exit face of crystals. This mirror has a reflectivity of ˜99.9% at the fundamental wavelength. On the other hand, the second harmonic generated (SHG) beam is directed by output turning mirror 120 into an AR coated, PM fiber, meant for that wavelength, through collimating plano convex lens 122 and focusing aspheric lens 124. This setup allows for high efficiency of beam coupling in the fiber.

The cavity includes two concave mirrors, 108 and 116 (which may be custom cut), and Brewster cut periodically poled crystals (for example, PPKTP crystals). The radii of curvature of mirrors depend on choice of preferred waist size at the center of crystal as described earlier. The input coupler is AR coated on input side and has a reflectivity R such that R˜1−L, where L is the net cavity loss. The radii of curvature of mirrors, the length of crystal and transmission of coupler have to be tailored in parallel to reduce heating effects in the crystal and to gain maximum efficiency. The output mirror is a standard high reflector (T=0.01%, R>99.9%) at fundamental wavelength.

The round trip length of cavity is adjusted by mounting the output mirror 116 on a piezo 118. The length is servo locked to the input laser frequency by maximizing the laser build-up in the cavity as monitored with photodiode 112. Unlike conventional technique of collecting light weakly transmitted from high reflector for phase locking, the present invention uses beam reflected at Brewster angle by the crystal. There are two advantages, one is it contributes towards a compact design and secondly, facilitates while cavity alignment to see if beams hitting clean on entrance side of crystal and to see if incoming laser is lining up with circulating beam. Also, in the present invention the small size of high reflector 116 and piezo 118, shown in FIG. 7 (which may also be custom cut), allow for high modulation frequency (˜40 kHz) to be used in locking, reducing sensitivity to flicker (lit) noise on top of DC high voltage. This contributes to the power stability of harmonic generation. The fundamental and harmonic beams are conveniently separated from each other while exiting the crystal (negligible Fresnel loss expected for harmonic generation from the near Brewster exit angle). This helps to have a low intrinsic cavity loss and reduce cost of production by avoiding the need to use a more expensive dichroic mirror.

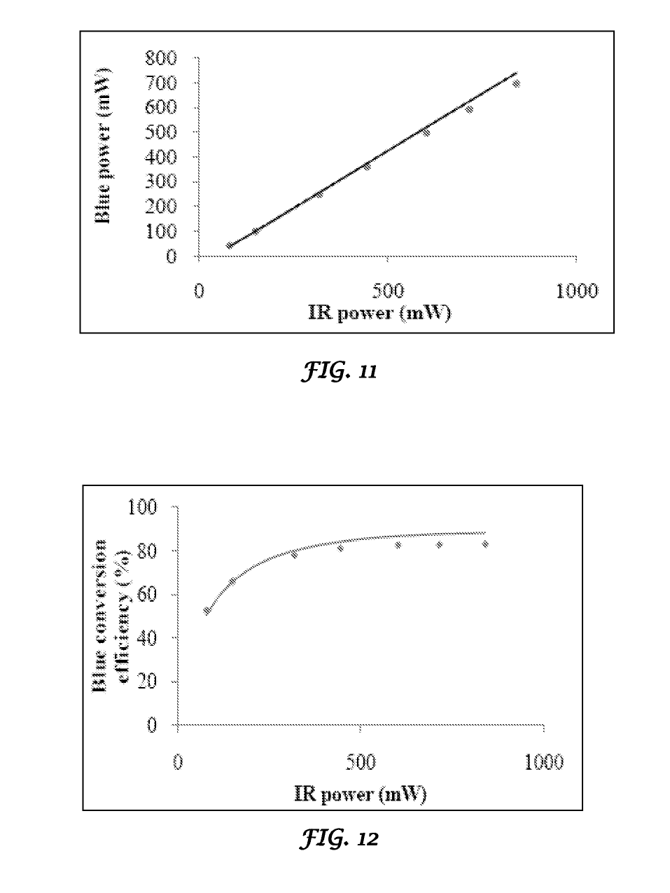

FIG. 2A illustrates monolithic cavity assembly with an aluminum cavity plate 202 as the base for the respective mounts housing the optical elements (104-124) shown in the schematic of FIG. 1. Threaded screws with plastic washers 218 shown in FIGS. 2A and 2B are to be moved through screw holes 238 on the plate. These are meant to hold the base plate 202 securely onto the box (not shown) in which entire cavity assembly along with laser and PM fibers is housed. Here plastic washers help insulate base plate from external electrical connections since they are mounted on two separate thermoelectric temperature controllers shown in FIG. 10. As shown in FIG. 2B, a set of six screws 226 are to be moved through counter bore screw holes 230, 234, 242 and slots 228 made through bottom of the plate 200, shown in FIG. 2C, to clamp mounts on top side of base plate at those positions respectively as depicted clearly in FIGS. 2A and 2B. FIG. 2B also shows pair of pin-holes 234 and 242 on plate 202 for corresponding pins 232 and 240 located on their respective mounts. The crystal is snug fit into plane defined by pins 232 even without screw clamping. This enables to remove crystal easily, if needed, for making some measurements or adjustments. The detector is clamped in with a clamping screw moved through screw hole 246. Hole 244 is made of diameter to fit a thermistor. Positions of all the holes are designed so that each optical element of cavity 102-124 in their respective mounts is placed at distance from each other corresponding to cavity parameters. The design enables for horizontal tilt of more than 4 degrees built into each of flexure mounts. Each of these components can be conveniently pulled out and placed back in with minimal post adjustment. The input and output fiber mounts 206 can be translated as well, due to slots 228 cut in the plate 202. Few modifications like enabling screw clamping from top of mounts rather than bottom side are possible.

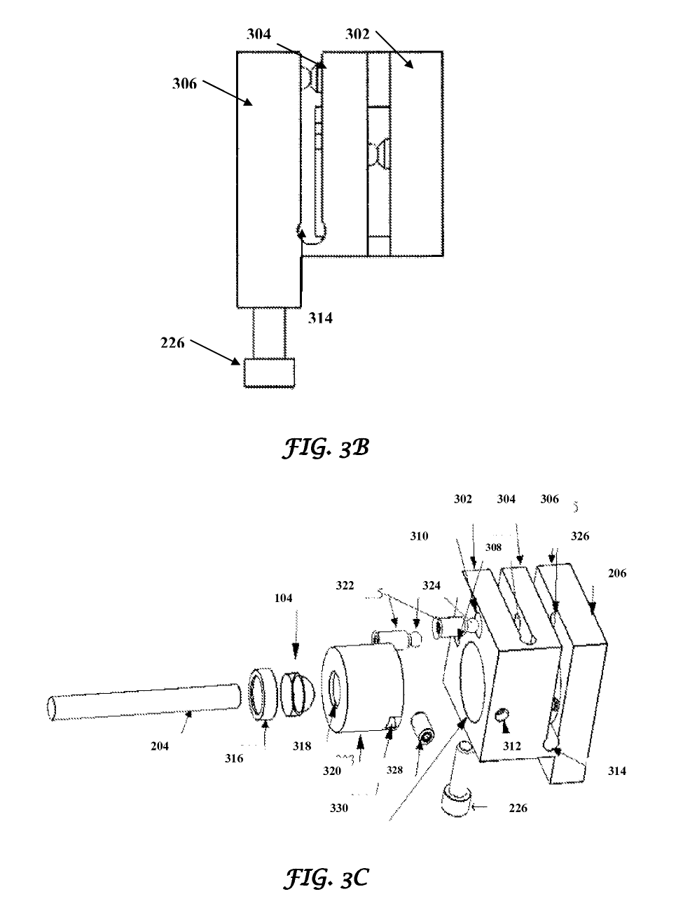

Flexure mounts 206, shown in FIG. 2A, housing optical elements 104, 122 and 124 are identical in their construction. FIGS. 3A and 3B show their isometric and side view. Angle polished, AR coated, single mode, polarization maintaining fiber inserted in a ferrule 204, designed for fundamental wavelength is mounted in a fiber connector FC/APC. This connector is attached to the flexure mount 206 such that slow axis of PM fiber is aligned in the optical plane of cavity. Similarly PM patch cord 224, designed for harmonic wavelength, AR coated at both ends, is mounted in a fiber connector attached to the output fiber mount. This is one of the features of our cavity, which enables convenient portability of SHG beam for any desired application.

FIG. 3C shows exploded view of the input fiber mount with optical elements and the construct of their houses 204, 316, 318, and 320. Alignment of laser beam coming out of 204 with the optic axis of lens could be critical issue. In the present invention aspheric lens 104 is mounted in a case 320 with inner diameter big enough to allow slight motion for the lens before clamping it with glue. Lens sits in a ring 316, which isolates its side facing fiber 204 from brushing against the case 320 and hence prevents any scratches. The arrangement has been shown in FIG. 3D. The case 320 is fine threaded on its exterior and is to move through a fine threaded hole 330 in the flexure mount 206 to position lens with respect to tip of the fiber. Slot 330 allows for external key to rotate the lens. Aperture size 318 on the case is large enough to allow access of clear aperture of the aspheric lens. Slight squeezing or clamping force can be applied to the case 320 via soft plastic set screw 328 moving through threaded screw hole 312 on the side of the flexure mount. This force applied perpendicular to the optic axis ensure for stability of beam steering and to hold firm against acoustic or thermal vibrations.

Input fiber mount and fiber connector: Spherical aberration arising from 4.5 mm aspheric IR lens is largely circumvented by purposely misaligning input laser beam to hit bit off the optic axis. This care was taken at the time of gluing the fiber connector to the mount. With this naturally built-in astigmatism in the laser beam, the inventors succeeded in obtaining 96% mode matching with the one intrinsic to the cavity. With this arrangement, the inventors were also able to avoid additional beam shaping and aberration reduction lenses.

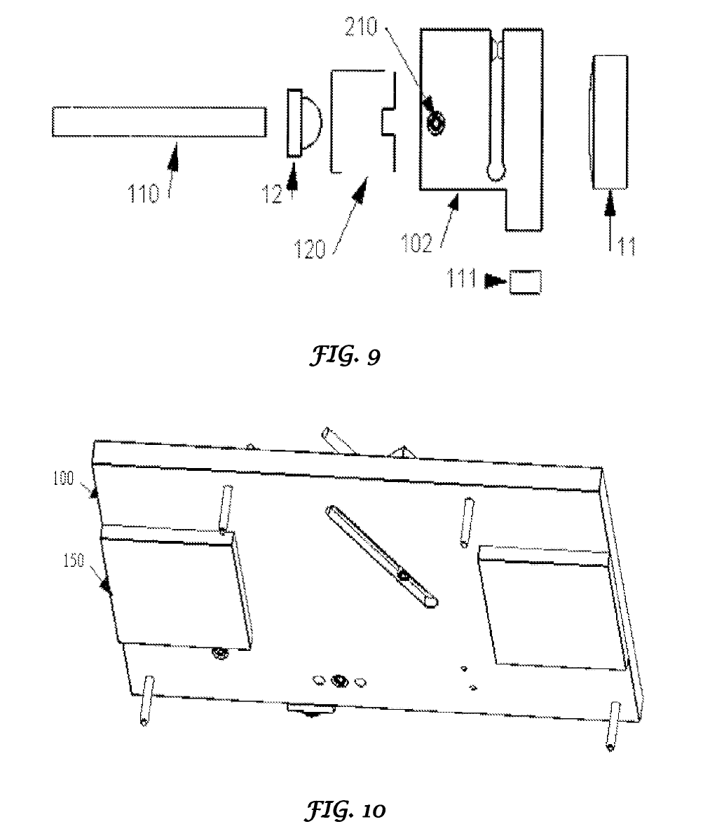

The exploded view of output fiber mount shown in FIG. 9 has similar arrangements as that of input fiber mount. To focus the beam into the core of PM fiber 224, aspheric lens 124 is used. The distance of this lens from center of cavity is such that after passing though this lens, waist size of SHG beam is close to core radius of fiber. Since the lens is designed for collecting collimated beam, SHG beam coming from turning mirror 120 is first received by plano convex lens 120. The focal length of this lens is equal or close to distance of aspheric lens to the center of crystal in the cavity. As shown in FIG. 9 aspheric lens is housed in case 248 with inner diameter equal to that of lens 124. Soft plastic set screw 328 locks the case in place. Similar to sketch shown in FIG. 3C, all the flexure mounts 206, 208, 210, 216 and 220 are clamped from bottom with threaded screws 226 to the base plate 202. Threaded pair of set screws 322 are to be rotated within and axially advanced through threaded screw holes 308. This allows for two axis positioning of moveable face 302 and middle 304 surfaces relative to the stationary front surface 306. Rotation of adjustment screw is made by pressing against a hard, fine polished ball, preferably made out of material like steel, placed in the depression 326 made in front surface 306 and a similar depression made in mid surface 304 as shown in FIG. 3B. This allows for smooth tuning of both axis and excellent mechanical stability. As a specific example, flexure mount could be designed for vertical and horizontal tilt of ±4° by cutting a slot of 63 mils between each surface of the mount. Flexure mounts may be made out of Beryllium copper, which has better elastic and thermal properties, or Aluminum with similar properties. Both these materials are easy to machine.

As a practical consideration, depending on material used flexure pivotal thickness 314 ranges from 25-35 millimeters and determines the tilt stiffness. The point of rotation is located at the center of Front and mid surface, which enables symmetric tilt. Adjustment is easily made using an Allen wrench. Clearance hole 310 allows for inserting Allen wrench to move screws placed in 308. So by avoiding use of bulky knobs for adjustment and small size of each of flexure mounts, plurality of these mounts can be arranged in a compact and efficient way, without introducing any optical distortion. The cost of production is also lowered since each flexure mount is a monolithic unit and doesn't involve the welding process to join separate parts and strings for flexing motion.

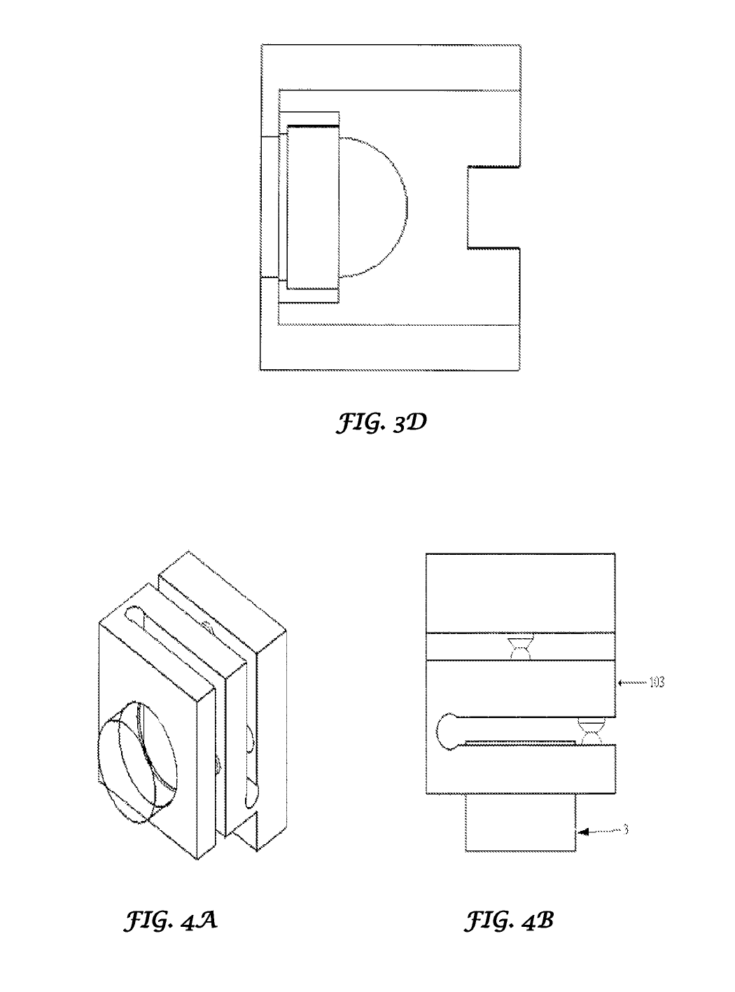

FIG. 4A is the isometric view of input flexure mount with turning mirror for fundamental beam. FIG. 4B shows input turning mirror 106 mounted on the flexure mount 208 such that normal at its center lies in the optical plane and is at 45° with respect to incident beam, as depicted in FIG. 2A. The mirror is a custom cut, standard flat high reflector at the fundamental wavelength. The mirror is place in the mount aperture such that it's back surface lies either in same plane of back side of the mount face, or sticks out a bit as illustrated in FIG. 4B. Similarly output turning mirror 120 is a flat, standard high reflector at harmonic wavelength and is mounted on flexure mount 220 as shown in FIG. 8. It directs the SHG beam towards output PM fiber 224 at 90° with respect to incident beam. The normals to both of above turning mirror surfaces lie in the same optical plane of the cavity.

As shown in FIG. 2A and FIG. 5A, input coupler 108 is mounted, on side of flexure mount 210 facing the cavity, via ring 502, which assists in securing the coupler firmly in place on the mount at position 504. The ring can be fastened with glue or soft screw 328 pressing against it from top side of the face. FIG. 5B is the exploded view of input flexure mount with partial reflector and FIG. 5C shows the rear view of input flexure mount with partial reflector. The advantage of this arrangement is in easy cleansing of sensitive, reflective side of coupler. The coupler is positioned such that normal to its center is in plane of optic axis and symmetric about beam coming from high reflector and moving toward crystal. Similarly the output high reflecting mirror 116 fastened to high voltage side of piezo 118 is mounted on side of flexure mount 216 facing the cavity, as shown in FIG. 7A and FIG. 2A. Both, mirror and piezo have been placed at the pivotal edge of flexure mount 216 which defines the axis of rotation for horizontal tilt. This allows to easily translate mirror in a plane defined by positions of pins 240, such that SHG beam can cleanly escape while IR getting reflected back into cavity, as seen in FIG. 1. In addition, translation of mirror along the arc with its center at the flexure pivot, due to horizontal tilt of mount is minimized since mirror is sitting close to center of axis about which its being tilted which leaves the beam separation unaffected. The situation is well depicted in FIG. 7B with mirror supposed to be located at positions of Objects 1 and 2, i.e., Ob1 and Ob2. The mount is clamped to the pins 240 with screw 704 squeezing onto the flex part of the mount 702. The flex part 702 is formed by slotting the bottom of leg of back side of mount. As shown in FIG. 7C, an alternate arrangement would be to cut a slot in the seat at back end and move a pair of clamping screws 712 through it to be received by tapped holes made at corresponding locations on the base plate. These features speed up cavity alignment process, a key factor for commercial application

FIG. 6A shows an exploded view of crystal mount assembly comprising of mount base, crystal, cover, pins and screws. The base of the mount and cover are cut on the sides at angles which matches with the Brewster angle cut of the crystal. Contacts between crystal surface and base are mediated by thermal compound for better thermal conductivity. The length of mount is such that crystal surface facing input coupler, sticks out by few mils to allow for clean entrance of fundamental beam. The exit side of crystal is either flush with mount or sticks in a few mils to allow complete contact of bottom side of crystal with the mount base. This is essential since during nonlinear conversion most of harmonic generation is concentrated at the exit point of crystal and hence most heat generated from its absorption. In addition, the cover of mount is designed such that it can cling on to the crystal surface to allow for better thermal contact with help of thermal compound applied to it as well. This feature is enabled by free fit clearance holes 604 for the pair of small screws 602 which lock the cover on to the base via threaded screw holes 606. Cavity base is mounted on pins 232 via close fit holes 610 shown in FIG. 6B. Additionally the base is fastened to the base plate 202 with clamping screw 226. To be noted, thermal compound should be coated at the bottom of input cavity mount 210, crystal mount base and output cavity mount 216. This is essential to maintain uniform temperature for whole cavity and to be able to tune crystal temperature for phase matching.

Some of possible changes are use of different material or the combination like instead of Aluminum or Beryllium copper to purely Al or BeCu or simply copper, and metals with similar properties of thermal conductivity, machinability and rigidity. Also some modification in clamping flexure mounts like one illustrated in FIG. 7C and the crystal mount from top side of base plate are possible. These will enhance the speed of lining up the cavity.

IR diode laser doubling with PPKTP: The present invention includes high efficiency resonant doubling (e.g., at 486 nm) using periodically poled KTP (PPPKT). A stable blue power of 700±5 mW was obtained using the 840 mW output power of a Fiber Bragg Grating (FBG) stabilized Polarization Maintaining (PM) fiber coupled Infrared (IR) semiconductor laser. This gives an overall conversion efficiency of 83%. To obtain this result, all losses in the system were carefully studied and minimized.

Blue diode lasers are commercially available, but they do not yet match the performance of the well developed IR semiconductor lasers. Nonlinear doubling these IR lasers offer an alternative blue laser source of high power. We use a continuous wave, compact, high power, PM fiber coupled, single transverse and longitudinal frequency source at 972 nm. Such lasers are very convenient sources for frequency doubling [1], and various methods have been used. For instance, waveguide doubling is attractive but has limitation in terms of scaling with high IR power [2]. Thus, a resonant cavity design can be used to circumvent low single pass efficiency of non-waveguide doubling. Polzik and Kimble have reported 560 mW of directly measured power at 80% net efficiency at 540 nm [3] from KTP using type II phase matching. Kaneda, et al., reported [4] 700 mW of 488 nm light using 6 W of 808 nm to optically pump a 976 nm semiconductor laser (OPSL). But quasi phase matching can be preferable to birefringence techniques since it is intrinsically free of walk-off, allows access to largest nonlinear tensor element and has a better tolerance for angular acceptance, and promises better overall power and efficiency. Materials like periodically poled LiNbO3 (PPLN), LiTaO3 (PPLT) and KTiOPO4 (PPKTP) are commercially available. We chose to use PPKTP in this work since the other two can suffer from photorefractive damage at high intensity. PPKTP has recently been used to achieve 225 mW at 423 nm [5], 234 mW at 461 nm [6], 330 mW at 426 nm [7] and 318 mW at 404 nm [8].

The performance of this laser source can be phenomenologically modeled and laser chip parameters such as output facet reflectivity, gain, transparency current, loss and fiber coupling efficiency are measured using a simple probe laser. The beam was coupled into the cavity with a waist size of 48 μm close to average of 44 μm (horizontal) by 51.2 μm (vertical) designed to be at center of crystal 22 in cavity. The single pass efficiency measured with this waist size is 1.06%/W.

A summary of the important cavity parameters is shown in Table 1.

TABLE 1
Cavity Parameters.

| | Transmission | | Linear | Net Blue | |
|---|---|---|---|---|---|
| | of input | Coupling | cavity | absorption | Single pass |
| Parameter | coupler | efficiency | loss | loss | efficiency |
| Value | 9.5% | 96% | 0.3% | 5% | 1.06%/W |

The IR beam and blue laser beams are conveniently separated from each other by 4.38° while exiting the crystal (blue Fresnel loss of 0.3% expected from the near Brewster exit angle) and reduces production costs by avoiding the need to use a more expensive dichroic mirror. The expected blue output power was calculated (using the cavity parameters) versus the IR input power. This is plotted in FIG. 11, and compared to the experimentally measured blue power. The agreement is within the parameter errors except for slight but progressively lower performance at high powers. A similar plot of overall efficiency versus input power is shown in FIG. 12.

A stable and locked continuous wave (cw) blue output power of 700 mW has been obtained from the 840 mW output power of an IR laser using a compact resonant doubling cavity. The overall or net conversion efficiency is 83%. The difference between this and the 88% calculated efficiency based on the cavity parameters is presumably due to thermal effects and is currently being studied.

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, MB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skilled in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

### REFERENCES

U.S. Pat. No. 7,027,209: Optical Resonant Frequency Converter.

U.S. Pat. No. 5,027,361: Efficient Laser Harmonic Generation Employing A Low-Loss External Optical Resonator.

U.S. Pat. No. 7,460,570: Green Coherent Light Generating Device using Even Nonlinear Crystals.

U.S. Pat. No. 5,206,868: Resonant Nonlinear Laser Beam Converter.

[1] T. Pliska, et al., “A compact, narrow-band, and low-noise 800-mW laser source at 980 nm,” SPIE Volume 5738, n 1, 380-7, 2005.

[2] A. Khademian and D. Shiner, “Evaluation of a 486 nm Single Frequency Source Using an MgO:PPLN Waveguide Doubled Semiconductor Laser,” JWA33, CLEO, 2007.

[3] Z. Y. Ou, et al., “85% efficiency for cw frequency doubling from 1.08 to 0.54 μm,”Opt. Letters, 17,9, 640-642 (1992).

[4] Y. Kaneda, et al., “Continuous-wave all-solid-state 244 nm deep-ultraviolet laser source by fourth-harmonic generation of an optically pumped semiconductor laser using CsLiB6O10 in an external resonator.”Opt. Letters, 33,15, p 1705-1707, 2008.

[5] F. Torabi-Goudarzi and E. Riis, “Efficient cw high-power frequency doubling in periodically poled KTP,” Opt. Commun 227, 389-403 (2003).

[6] R. Le. Targat, J.-J. Zondy, and P. Lemonde, “75%-Efficiency blue generation from an intracavity PPKTP frequency doubler,” Opt. Commun 247, 471-481 (2005).

[7] F. Villa, A. Chiummo, E. Giacobino, and A. Bramati, “High-efficiency blue-light generation with a ring cavity with periodically poled KTP,” J. Opt. Soc. Am. B 24, 576-580 (2007).

[8] J. H. Lunderman, et al., “High power 404 nm source based on second harmonic generation in PPKTP of a tapered external feedback diode laser,” Opt. Express, 16,4,2486-2493 (2008).

1. A nonlinear resonator apparatus comprising:
a fiber coupled to a light source that generates a first light beam;
a ring cavity in optical alignment with the first light beam from the light source, wherein the cavity comprises:
two concave mirrors; and
one or more Brewster-cut periodically poled crystals with a S-polarized component of the first light beam reflected off of a Brewster surface serving as a feedback signal for a servo locking of a cavity length to a first light frequency, wherein the servo locking is done at a high frequency.

2. The apparatus of claim 1, wherein the crystal comprises a periodically poled LiNbO₃ (PPLN), a LiTaO₃ (PPLT), a KTiOPO₄ (PPKTP) or any suitable periodically poled crystals.

3. The apparatus of claim 1, wherein the apparatus does not include a dichroic mirror in the cavity.

4. The apparatus of claim 1, wherein the apparatus performs a non dichroic mirror based separation of the first light beam and a second light beam or a second harmonic.

5. The apparatus of claim 1, further comprising a coupling aspheric lens that is positioned along an optical axis of a second separated light beam that exits the cavity, wherein the second beam exits the cavity at near Brewster angle at which the first light beam exits.

6. The apparatus of claim 5, further comprising an input PM fiber in optical alignment with the coupling aspheric lens.

7. The apparatus of claim 1, wherein the apparatus polarizes a circulating power of the first and the second light beams in a direction parallel to an orientation of periodic poling direction within the crystal.

8. The apparatus of claim 1, wherein the first light source is a laser.

9. The apparatus of claim 1, wherein the first light source is an infrared laser.

10. The apparatus of claim 1, wherein the first, second or both light beams traverse an optical fiber.

11. The apparatus of claim 1, wherein the apparatus comprises a customized output mirror on a customized flexure mount, wherein the mount is translated in a plane perpendicular to the incoming second light beam.

12. The apparatus of claim 1, wherein the entire apparatus is made monolithic and fiber to fiber coupled by a coupling of the second light beam into a fiber by a beam shaping optics arrangement.

13. A method of separating light wavelengths comprising the steps of:
generating a first light beam directed at a cavity in optical alignment with an laser beam from the laser source, wherein the cavity comprises:
two concave mirrors; and
one or more Brewster-cut periodically poled crystals with a S-polarized component of the first light beam reflected off of a Brewster surface serving as a feedback signal for a servo locking of a cavity length to a first light frequency, wherein the servo locking is done at a high frequency.

14. The method of claim 13, wherein the crystal comprises a periodically poled LiNbO₃ (PPLN), LiTaO₃ (PPLT), KTiOPO₄ (PPKTP) or any suitable periodically poled crystals.

15. The method of claim 13, wherein the apparatus does not include a dichroic mirror in the cavity.

16. The method of claim 13, further comprising a coupling aspheric lens that is positioned along an optical axis of a second separated light beam that exits the cavity, wherein the second beam exits the cavity at near Brewster angle at which the first light beam exits.

17. The method of claim 16, further comprising an input PM fiber in optical alignment with the coupling aspheric lens.

18. The method of claim 13, wherein the first light source is a laser.

19. The method of claim 13, wherein the first light source is an infrared laser.

20. The method of claim 13, wherein the first, second or both light beams traverse an optical fiber.

21. A monolithic, nonlinear resonator comprising laser source:
an infrared laser source that generates a first light beam;
a cavity in optical alignment with the first light beam from the light source, wherein the cavity comprises:
two concave mirrors; and
one or more Brewster-cut periodically poled crystals with a S-polarized component of the first light beam reflected off of a Brewster surface serving as a feedback signal for a servo locking of a cavity length to a first light frequency, wherein the servo locking is done at a high frequency.

22. The apparatus of claim 21, wherein the crystal comprises a periodically poled LiNbO₃ (PPLN), LiTaO₃ (PPLT), KTiOPO₄ (PPKTP) or any suitable periodically poled crystals.

23. The apparatus of claim 21, wherein the apparatus does not include a dichroic mirror in the cavity.

24. The apparatus of claim 21, wherein the apparatus performs a non dichroic mirror based separation of the first light beam and a second light beam or a second harmonic.

25. The apparatus of claim 21, further comprising a coupling aspheric lens that is positioned along an optical axis of a second separated light beam that exits the cavity, wherein the second beam exits the cavity at near Brewster angle at which the first light beam exits.

26. The apparatus of claim 25, further comprising an input PM fiber in optical alignment with the coupling aspheric lens.

27. The apparatus of claim 21, wherein the apparatus polarizes a circulating power of the first and the second light beams in a direction parallel to an orientation of periodic poling direction within the crystal.

28. The apparatus of claim 21, wherein the first light source is a laser.

29. The apparatus of claim 21, wherein the first light source is an infrared laser.

30. The apparatus of claim 21, wherein the first, second or both light beams traverse an optical fiber.

31. The apparatus of claim 21, wherein the apparatus comprises a customized output mirror on a customized flexure mount, wherein the mount is translated in a plane perpendicular to the incoming second light beam.

32. The apparatus of claim 21, wherein the entire apparatus is made monolithic and fiber to fiber coupled by a coupling of the second light beam into a fiber by a beam shaping optics arrangement.
